(19) United States
(12) Patent Application Publication
(10) Pub. No.: US 2009/0044971 A1
(43) Pub. Date: Feb. 19, 2009

(54) Printed Wiring Board, Process for Producing the Same and Usage of the Same

(75) Inventors: Tatsuo Kataoka, Saitama (JP); Hirokazu Kawamura, Saitama (JP)

Correspondence Address: THE WEBB LAW FIRM, P.C., 700 KOPPERS BUILDING, 436 SEVENTH AVENUE, PITTSBURGH, PA, 15219, US

(73) Assignee: MITSUI MINING & SMELTING CO., LTD., Tokyo (JP)

(21) Appl. No.: 12/093,899

(22) PCT Filed: Nov. 13, 2006
(86) PCT No.: PCT/JP2006/322580

§ 371 Date: May 15, 2008

(30) Foreign Application Priority Data
Nov. 15, 2005 (JP) 2005-330183
Jan. 27, 2006 (JP) 2006-018929

(51) Int. Cl. B32B 37/12; H05K 1/09; G03F 7/20

(52) U.S. Cl. 174/257; 430/314; 156/292

(57) ABSTRACT

The printed wiring board includes an insulating base and a plurality of wirings formed on the surface of the insulating base, wherein the wiring circuit has a conductive undercoat layer formed on the surface of the insulating base, a Cu nodule layer formed on the upper surface of the undercoat layer, a cover plating layer formed on the upper surface of the Cu nodule layer and a first metal plating layer formed on the upper surface of the cover plating layer, and on the upper surface of the wiring circuit, a protruded and depressed surface attributable to protrusions and depressions of the upper surface of the Cu nodule layer is formed. The printed wiring board can be produced by depositing the above metal layers such as the Cu nodule layer with regulating a sidewall surface of a pattern formed from the photosensitive resin. Ruther conductive bonding is possible by the use of an adhesive only.

### TECHNICAL FIELD

The present invention relates to a printed wiring board having a Cu nodule layer, a process for producing the same, and usage of the printed wiring board.

### BACKGROUND ART

An output side outer lead and an input side outer lead of a printed wiring board, such as a TAB tape of a three-layer structure consisting of an insulating film, an adhesive layer and a wiring pattern formed from a conductive metal foil or a COF tape of a two-layer structure consisting of an insulating film and a wiring pattern composed of a conductive metal foil directly formed on the insulating film, are each electrically connected to a circuit part of a liquid crystal panel or a rigid printed wiring board with an anisotropic conductive film (ACF), as shown in FIG. 4. Referring to FIG. 4, numeral 10 designates an insulating base such as a polyimide film, numeral 50 designates LCD, numeral 40 designates an anisotropic conductive adhesive film, numeral 41 designates a conductive particle, and numeral 42 designates an adhesive. The wiring pattern 43 formed on the surface of the insulating base 10 is electrically connected to the LCD through the conductive particles 41, and the LCD 50 and the insulating base 10 are bonded and fixed to each other with the adhesive 42.

As fining of pitches of gold bumps in driver IC chips has been promoted with enhancement of resolution of liquid crystal screens in recent years, it has become necessary to form a circuit having a fine inner lead pitch of not more than 20 μm also in printed wiring boards for IC mounting, such as COF.

It has been thought in the past that in order to form such a fine printed wiring board, a conductive metal foil used needs to be thinned. For example, in the case where a circuit having a line width of not more than 10 μm and a wiring gap of not more than 10 μm is intended to be formed by etching, there resides a problem that the desired fine line width (e.g., line width of not less 6 μm) cannot be obtained unless the thickness of the conductive metal foil (e.g., electrodeposited copper foil) that becomes a conductor is reduced to not more than the line width (e.g., not more than 5 μm). Moreover, if the line width is small, there is a possibility of further thinning of Cu or inclination of pattern caused by copper erosion due to sagging of tin plating in the inner lead bonding.

However, if the thickness of the conductive metal foil such as a Cu foil is reduced to not more than 5 μm, reliability of connection by the anisotropic conductive film (ACF) is markedly lowered. The reason is presumably that there is mechanical restriction attributable to that the sizes of the conductive particles contained in the anisotropic conductive adhesive are large and the thickness of the adhesive sheet that becomes a binder is large for the thickness of the conductive metal foil such as a Cu foil or the pitch.

By the way, technique to form ultra-fine pitch wiring patterns by a semi-additive method has advanced recently, and this technique makes it possible to form a wiring pattern having a pitch width of not more than 20 μm even if the conductor such as Cu has a large thickness of 8 μm. Also a printed wiring board having such a fine wiring pattern needs to be connected with the ACF. The ACE used herein contains particles having a diameter of several μm as conductive particles, and by allowing a large number of the conductive particles to be present between upper and lower two different printed wiring boards, conduction between the upper and the lower two different wiring boards is established through the anisotropic conductive particles interposed between the upper and lower two wires. In the case of such electrical connection by the anisotropic conductive particles, insulation resistance between adjacent wires tends to be lowered if a direct voltage is applied between the wiring patterns for a long period of time under the high-temperature high-humidity conditions, such as those of 85° C.×85% RH, and especially in wiring patterns of fine pitch, such a tendency becomes conspicuous.

Under such actual circumstances, development of a novel method other than the anisopropic conductive bonding as a method to establish electrical connection between wiring boards has been eagerly desired.

As a method to establish electrical connection between wiring patterns without using such an anisotropic conductive adhesive as above, there has been disclosed in a patent document 1 (Japanese Patent No. 2660934) a method comprising forming, by electroplating, Cu nodules (dendritic Cu crystals) on a lead portion of a printed wiring board having a wiring pattern formed by etching, then electrically connecting a lead of an electronic component or a LCD panel to the lead of the wiring board circuit through the nodules, and thermally contact-bonding them by means of a bonder using a sheet adhesive to electrically connect the electronic component to the wiring pattern.

According to this method, an electrically connected stable state can be formed because electrical connection is established by a large number of nodules formed on the wiring pattern surface. In order to form such Cu nodules (dendritic Cu crystals), however, it is necessary to supply plating power for forming Cu nodules through wiring after the wiring pattern is formed by etching a copper foil, and further, it is necessary to form Cu nodules on the lead portion, etc. of the wiring pattern formed by etching. If Cu nodules are formed on the lead portion of the wiring pattern as above, the growing direction of the Cu nodules and the like cannot be controlled, and the Cu nodules not only grow on the upper surface of the wiring pattern that contributes electrical connection but also grow outward from the side surface of the wiring pattern.

In the recent printed wiring boards, wiring patterns are formed extremely densely, and there is no room for installing wiring that supplies electric power for forming such Cu nodules. Further, if wiring that supplies electric power for forming such Cu nodules is separately provided, there occurs a problem that the degree of freedom in design of a printed wiring board is markedly lowered. Furthermore, such Cu nodules are formed on the lead portion, but of the Cu nodules, Cu nodules that contribute to establishment of electrical connection are only those formed on the upper surface of the wiring pattern. Therefore, the Cu nodules having grown from the side surface of the wiring pattern are capable of becoming a cause of short-circuit in the recent printed wiring boards having wiring patterns of fine pitches because the nodules come into contact with one another between the adjacent wiring patterns. If the heights of the nodules are decreased in order to prevent this short-circuit, reliability of electrical connection is lowered.

For the above reasons, Cu nodules have not been positively utilized for the electrical connection between the printed wiring boards, and anisotropic conductive adhesives have been still employed.

Patent document 1: Japanese Patent No. 2660934

### DISCLOSURE OF THE INVENTION

### Problem to be Solved by the Invention

It is an object of the present invention to provide a printed wiring board, in which the section of a side face of a wiring circuit has a shape of an approximate rectangle that is not inclined or the section of a wiring pattern tends to be wider than the upper part, and extremely fine wiring circuits can be formed at a high density, and a process for producing the printed wiring board.

It is another object of the present invention to provide a printed wiring board which has, on the surface of a wiring circuit, protrusions capable of being utilized as electrical connection means in, for example, conductive bonding and which can be subjected to conductive bonding only with an adhesive component utilizing the protrusions, and a process for producing the printed wiring board.

It is a further object of the present invention to provide a printed wiring board, in which a Cu nodule layer is formed as a layer for forming a wiring circuit, the wiring circuit has a protruded and depressed surface attributable to the Cu nodule layer as the upper surface but has a side face that rises up approximately vertically to the insulating base, and on the surface of the wiring circuit where the Cu nodule layer has been formed, a first metal plating layer (preferably gold plating layer) is formed so as to cover the Cu nodule layer, and a process for producing the printed wiring board.

It is a still further object of the present invention to provide usage of the printed wiring board having protrusions and depressions on the upper surface of such a wiring circuit as above.

### Means to Solve the Problem

The printed wiring board of the present invention is a printed wiring board having an insulating base and a large number of wiring circuits formed on the surface of the insulating base, wherein the wiring circuit has a conductive undercoat layer formed on the surface of the insulating base, a Cu nodule layer formed on the upper surface of the undercoat layer, a cover plating layer formed on the upper surface of the Cu nodule layer and a first metal plating layer (preferably gold metal layer) formed on the upper surface of the cover plating layer, and on the upper surface of the wiring circuit, a protruded and depressed surface attributable to protrusions and depressions of the upper surface of the Cu nodule layer is formed. In the printed wiring board of the invention, the undercoat layer preferably comprises a conductive metal thin layer composed of a Ni—Cr alloy and a sputtering copper layer. The printed wiring board preferably has a semi-additive copper layer on the upper surface of the conductive undercoat layer.

The process for producing a printed wiring board of the present invention comprises forming a conductive undercoat layer for supplying plating current on a surface of an insulating base, forming a photosensitive resin layer on the surface of the undercoat layer, exposing and developing a pattern for forming a wiring circuit in the photosensitive resin layer to form a recess portion on the photosensitive resin layer, forming a Cu nodule layer inside the recess portion, forming a cover plating layer on at least the surface of the Cu nodule layer, further forming a first metal plating layer (preferably gold plating layer) on the upper surface of the cover plating layer formed on the upper surface of the Cu nodule layer to cover the Cu nodule layer, thereafter peeling the photosensitive resin layer and then removing the undercoat layer having been exposed by peeling the photosensitive resin layer.

That is to say, the process for producing a printed wiring board of the invention preferably comprises forming a photosensitive resin layer on a surface of a conductive metal thin layer laminated on an insulating base, exposing and developing the photosensitive resin layer to form a desired pattern, then forming a semi-additive copper layer on the pattern portion formed on the insulating base by a semi-additive method, then forming Cu nodules on the semi-additive copper layer, forming a cover plating layer on the Cu nodules to fix the Cu nodules, thereafter forming a first metal plating layer on the wiring circuit, then peeling the photosensitive resin layer to expose the conductive metal thin layer and dissolution-removing a part of the conductive metal thin layer where the wiring circuit has not been formed.

On the wiring circuit formed as above, a second metal plating layer is preferably formed by tin plating or the like to cover the wiring circuit with the second metal plating layer.

By the use of the printed wiring board produced as above, anisotropic conductive bonding can be carried out using only an adhesive containing no conductive particle. That is to say, when the printed wiring board having the wiring circuit that has on its surface protrusions attributable to the Cu nodule layer is bonded using an adhesive containing no conductive particle, the protrusions favorably function as electrically joining points, so that extremely highly reliable conductive bonding can be carried out.

In the printed wiring board of the invention formed as above, the width of the upper end and the width of the lower end of the section of the wiring circuit are approximately equal, and this wiring circuit is formed approximately vertically to the insulating base because growth in the lateral direction is regulated by the wall of the photosensitive resin. Further, the line width of the wiring circuit is equal to the width of a trench of the photosensitive resin formed by exposing and developing the photosensitive resin, and therefore, the line width of the wiring circuit can be reduced to the limit of exposure and development of the photosensitive resin. More specifically, the line width can be reduced down to a wavelength of light used for exposure. The upper end of the wiring circuit thus formed is provided with a large number of protrusions and depressions that are almost the same as the surface profile of the Cu nodule layer, and these protrusions can be used as electrical connection points in the conductive bonding. Furthermore, since the side face of the wiring circuit is regulated by the wall surface of the photosensitive resin in the formation of Cu nodules, the Cu nodules grow in the thickness direction of the wiring circuit, and growth of the Cu nodules in the lateral direction from the side surface of the wiring circuit is inhibited. Moreover, the side face of the wiring circuit rises up approximately vertically and very sharply to the sidewall of the Cu nodule layer of the wiring circuit, and the wiring circuit has a sectional shape of a rectangle. In addition, since the Cu nodules do not grow in the lateral direction, short-circuit is not brought about by the Cu nodules.

### EFFECT OF THE INVENTION

In the process for producing a printed wiring board of the invention, the photosensitive resin layer formed on the surface of the undercoat layer is exposed and developed to form a recess portion for forming a wiring circuit in advance, and in the recess portion, a plating layer such as a Cu nodule layer is laminated. Therefore, Cu nodules extend in the thickness direction of the wiring circuit, and growth of Cu nodules in the lateral direction of the wiring circuit is blocked by the wall surface of the photosensitive resin, so that short-circuit does not occur between the adjacent wiring circuits. Further, the upper surface of the Cu nodule layer constituting the wiring circuit is covered with a first metal plating layer (preferably gold plating layer), and the wiring circuit formed has a side face vertical to the insulating base and has a sectional shape of a rectangle or an approximate rectangle.

In such a rectangular wiring circuit, nodules rise up very sharply without growing in the lateral direction, so that further fining of wiring circuits is possible. Therefore, wiring circuits can be formed at a high density in the printed wiring board. Moreover, each plating layer to constitute the wiring circuit is formed by electroplating, and power necessary for this electroplating is supplied through the conductive metal thin layer and the sputtering copper layer laminated on the surface of the insulating base. Therefore, it is unnecessary to form wiring only for supplying electroplating power on the surface of the insulating base, so that the degree of freedom in design of a printed wiring board is increased.

On the upper surface of the wiring circuit formed in the printed wiring board of the invention, protrusions and depressions attributable to the formation of the nodule layer are formed, and by utilizing the protrusions present on the wiring circuit, conductive bonding can be carried out by the use of only an adhesive containing no conductive particle. Since any conductive particle is not contained in the adhesive part thus formed, reliability of conductive bonding is not lowered even in such a severe environment as allows the adhesive component to exhibit fluidity.

### BRIEF DESCRIPTION OF THE DRAWINGS

FIG. 1-1 is a group of sectional views each of which schematically shows an example of a section of a substrate produced in each step of the process for producing a printed wiring board of the present invention.

FIG. 1-2 is a group of sectional views each of which schematically shows an example of a section of a substrate produced in each step of the process for producing a printed wiring board of the present invention.

FIG. 2 is a sectional view schematically showing a state where one wire of a printed wiring board obtained by the process for producing a printed wiring board of the present invention is connected to a LDC substrate.

FIG. 3 is an enlarged sectional view schematically showing an enlarged side surface of a wiring circuit.

FIG. 4 is a sectional view showing a state where a conventional printed wiring board is bonded to a LCD substrate using an anisotropic conducive adhesive.

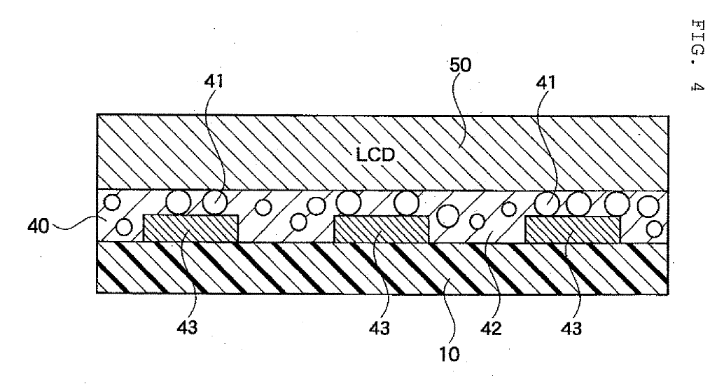

### DESCRIPTION OF SYMBOLS

1: section schematically showing section of wiring circuit whose outermost layer is gold plating layer (first metal plating layer)
2: section schematically showing section of wiring circuit whose outermost layer is tin plating layer (second metal plating layer)
10: insulating base (polyimide film)
11: reinforcing material
12: conductive metal thin layer
13: undercoat layer
14: copper sputtering layer
15: sidewall
16: photosensitive resin layer
17: recess portion
18: photomask
20: semi-additive copper layer
21: side edge
22: Cu nodule layer
24: cover plating layer
26: first metal plating layer (gold plating layer)
28: second metal plating layer (tin plating layer)
40: anisotropic conductive film
41: conductive particle
42: adhesive
45: adhesive
50: LCD

### BEST MODE FOR CARRYING OUT THE INVENTION

The printed wiring board of the invention and the process for producing the printed wiring board are described in detail hereinafter, making reference to the drawings.

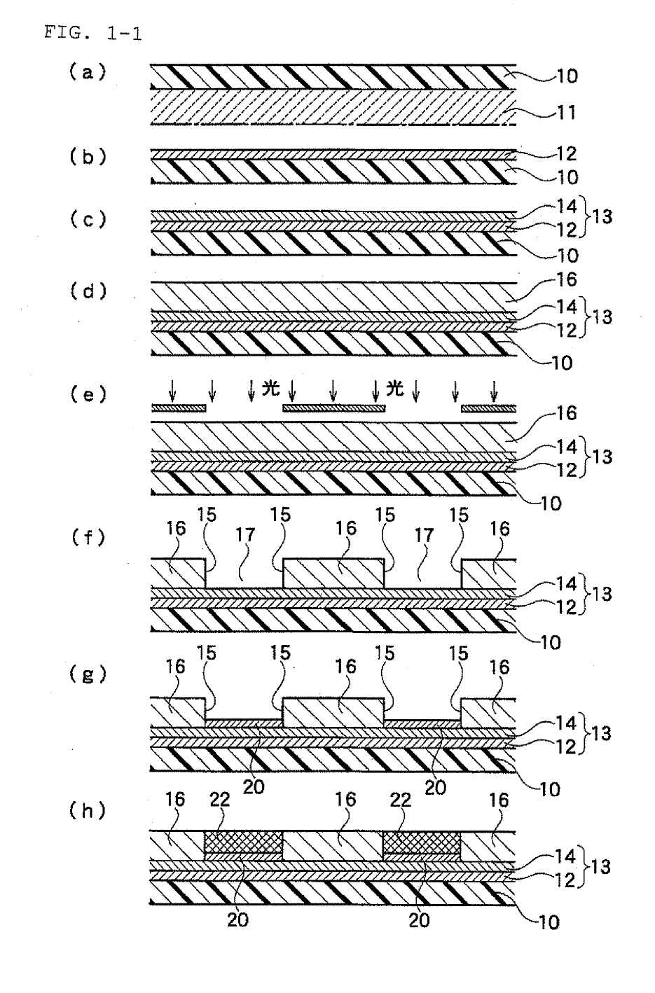

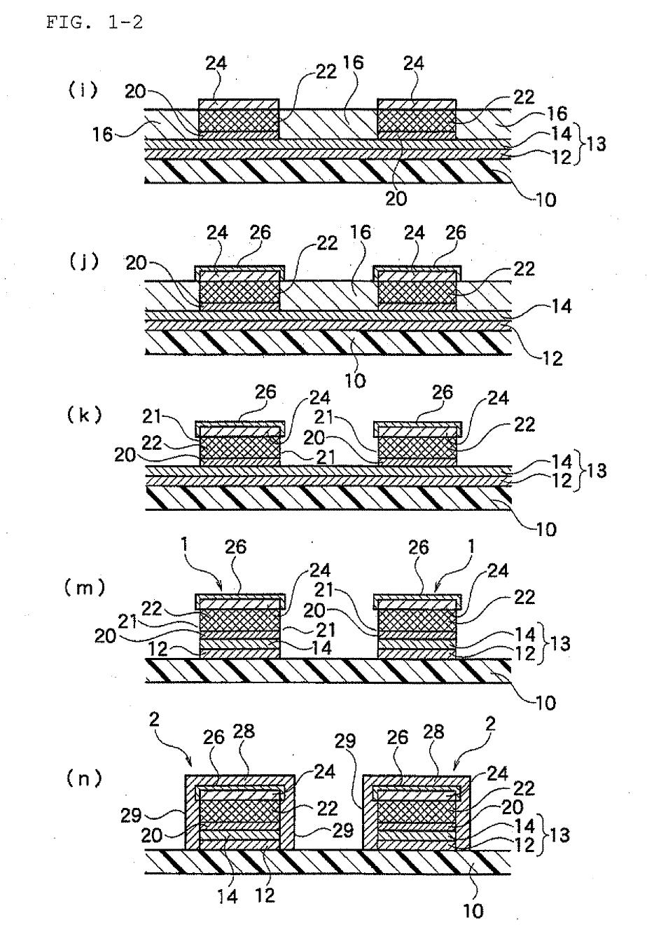

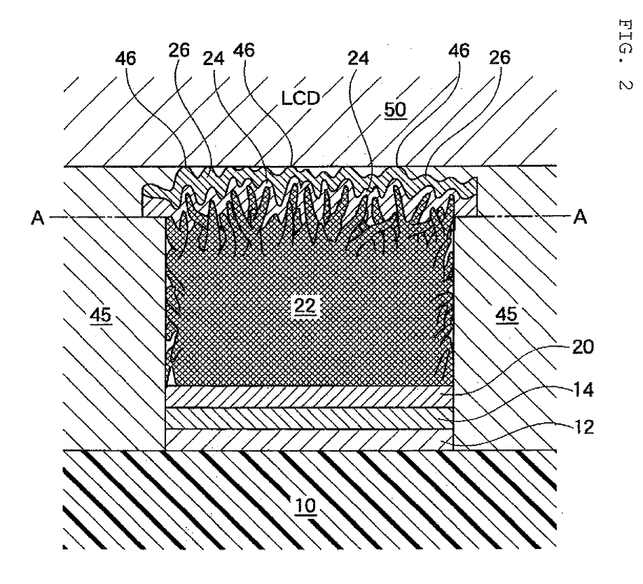

FIG. 1-1 and FIG. 1-2 are each a group of sectional views each of which schematically shows an example of a section of a substrate produced in each step of the process for producing a printed wiring board of the invention. In the process for producing a printed wiring board of the invention, a conductive metal thin layer 12 is formed on at least one surface of an insulating base 10, as shown in FIGS. 1(a) and 1(b). As the insulating base 10, usually used insulating bases, such as plates, films, sheets and prepregs made of insulating resins, can be used without any restriction. However, in order to continuously produce the printed wiring board of the invention by a reel-to-reel method, the insulating base 10 desirably has flexibility. Further, the insulating base 10 desirably has excellent chemical resistance because it sometimes comes into contact with an acid solution or an alkaline solution in the steps for producing the printed wiring board, and furthermore, the insulating base 10 desirably has excellent heat resistance because it is sometimes exposed to high temperatures. Moreover, the insulating base 10 is desired to be one that is not modified or deformed by the contact with water because a wiring pattern is formed using the insulating base 10 through plating steps. From these viewpoints, as the insulating base 10 for use in the invention, a heat-resistant synthetic resin film is preferably used, and particularly a resin film usually used for the production of a printed wiring board, such as a polyimide film, a polyamidoimide film, a polyester resin film, a fluororesin film or a liquid crystal resin film, is preferably used. Of these, a polyimide film that is excellent in properties of heat resistance, chemical resistance, water resistance and the like is particularly preferable.

In the present invention, the insulating film 10 does not need to be in the form of such a film as above, and may be an insulating base in the form of, for example, a plate made of a composite of a fibrous material and an epoxy resin.

In the case where an insulating base in the form of a film is used as the insulating base 10 in the invention, the thickness of the insulating film is in the range of usually 5 to 100 μm, preferably 5 to 70 μm. A resin film having a thickness of less than about 20 μm used as the insulating base 10 is often difficult to handle alone, and when such an insulating base 10 is used, a reinforcing material 11 for reinforcing the base may be arranged on the back surface, as indicated by chain lines in FIG. 1(a). The insulating base backed with the reinforcing material 11 may be also used irrespective of the thickness of the insulating base. Such a reinforcing material 11 is peeled off after a wiring circuit is formed. A release layer may be formed on the surface of an adhesive layer of the reinforcing material 11, and as the release layer, a silicone resin layer or the like may be formed. When the reinforcing material 11 is peeled off, the silicone resin layer formed as the release layer is transferred onto the back surface of the insulating base 10 and remains in some cases. The release layer made of a silicone resin or the like has high heat resistance, so that if such a release layer is transferred onto the back surface of the insulating base 10, staining of a bonding tool can be prevented. Although the reinforcing material 11 is indicated by chain lines in FIG. 1(a), description of the reinforcing material 11 is omitted in FIG. 1(b) and the subsequent figures.

In the present invention, the insulating base 10 may be provided with necessary through-holes, such as sprocket holes, device holes, slits for folding and positioning holes. These through-holes can be formed by punching, laser perforation or the like.

In the present invention, on at least one surface of the insulating base 10, a conductive metal thin layer 12 is formed. This conductive metal thin layer 12 is a layer that becomes an electrode when a metal layer is laminated on the surface of the conductive metal thin layer 12 by electroplating, and can be usually formed from a metal, such as nickel, chromium, copper or iron, or an alloy containing such a metal, such as nickel-chromium alloy, Ni—Zn or Ni—Cr—Zn. The method to form the conductive metal thin layer 12 is not specifically restricted provided that the above conductive metal is deposited on the surface of the insulating base 10. However, it is advantageous to form the layer by sputtering. By forming the conductive metal thin layer 12 by sputtering, the sputtered metal or alloy bites into the surface of the insulating base 10, and the insulating base 10 and the conductive metal thin layer 12 thus sputtered are strongly joined to each other. In the production of the printed wiring board of the invention, therefore, it is unnecessary to provide an adhesive layer between the insulating base 10 and the conductive metal thin layer 12.

In the present invention, it is preferable to form the conductive metal thin layer 12 using a nickel-chromium alloy, and when such a nickel-chromium alloy is used, the chromium content is in the range of usually 5 to 50% by weight, preferably 10 to 30% by weight. The undercoat layer formed by the use of a nickel-chromium alloy having such a chromium content is excellent in migration resistance and etching property, so that a sharp wiring circuit can be formed.

In FIG. 1(a), the insulating base 10 is shown, and in FIG. 1(b), a state where the conductive metal thin layer 12 is formed on one surface of the insulating base 10 is shown. The conductive metal thin layer 12 has a mean thickness of usually 10 to 1000 Å, preferably 50 to 50 Å. This conductive metal thin layer 12 is a layer which not only becomes an undercoat layer 13 but also supplies plating power when another layer is laminated thereon, so that this layer has only to have a thickness capable of supplying plating power in the lamination of another layer. By setting the thickness in the above range, removal of the layer after formation of a wiring circuit is facilitated.

After the conductive metal thin layer 12 is formed as above, a thin copper layer is preferably formed on the surface of the conductive metal thin layer 12, as shown in FIG. 1(c). In the present invention, this thin copper layer is preferably a copper sputtering layer 14 formed by sputtering copper. The conductive metal thin layer 12 and the copper sputtering layer 14 together become an undercoat layer 13 (in the present invention, the undercoat layer 13 is regarded hereinafter as a layer including the conductive metal thin layer 12 and the copper sputtering layer 14). This copper sputtering layer 14 can be formed by not only sputtering but also various methods such as vacuum deposition and electroless plating, but the copper sputtering layer 14 formed by sputtering can provide a copper metallic circuit having excellent interlaminar bond strength and high strength. Although this copper sputtering layer 14 is a layer containing copper as a main component, metals other than copper may be contained within limits not detrimental to the properties of this layer. The copper sputtering layer has a mean thickness of usually 0.01 to 5 μm, preferably 0.1 to 3 μm. By forming the copper sputtering layer 14 having such a mean thickness, affinity of the copper sputtering layer 14 for a copper layer formed on the surface of the copper sputtering layer 14 by a semi-additive method is enhanced.

After the copper sputtering layer 14 is formed as above, this layer can be used as it is in the subsequent step, but because an oxide film or the like is sometimes formed on the surface of the copper sputtering layer 14, the surface of the copper sputtering layer 14 is desirably subjected to pickling in a strong acid such as sulfuric acid or hydrochloric acid for a short period of time, followed by the subsequent step.

In the present invention, after the copper sputtering layer 14 is formed, the whole surface of the copper sputtering layer 14 is coated with a liquid photosensitive resin to form a photosensitive resin layer 16, as shown in FIG. 1(d). As for the resin to form the photosensitive resin layer 16, there are such a type that a portion irradiated with light is cured and is not dissolved in a developing solution and such a type that a portion irradiated with light is dissolved in a developing solution, and in the present invention, a photosensitive resin of any of these types is employable. A photosensitive resist in the form of a film, such as a dry film, may be used by laminating it. In the present invention, a liquid photosensitive resin is preferably used to form the layer 16 because a thin insulating base is used. Such a liquid photosensitive resin has a viscosity of usually 2 to 50 cps, preferably 5 to 30 cps, at the coating temperature.

The thickness of the photosensitive resin applied herein is preferably almost the same as that of a wiring pattern to be formed. For example, the coating thickness of the photosensitive resin is in the range of 5 to 20 μm, preferably 2 to 15 μm, and this is almost the same as the total thickness of a sputtering copper layer 20 and a Cu nodule layer 22 that are intended to be produced in FIGS. 1(g) and 1(f), i.e., 5 to 20 μm, preferably 2 to 15 μm. In FIG. 1, there is shown an example of a section of a printed wiring board wherein the coating thickness of the photosensitive resin is 9 μm and a wiring circuit in which the total of the thickness (2.5 μm) of a semi-additive copper layer 20 and the thickness (6.5 μm) of a Cu nodule layer 22 is 9 μm is formed. That is to say, there is shown an embodiment wherein the coating thickness of the photosensitive resin in the production of the printed wiring board is 9 μm and this coating thickness and the above total thickness are the same as each other.

The method to apply the photosensitive resin is not specifically restricted, and a coating device publicly known, such as a roll coater, a spin coater or a doctor blade, can be employed.

The photosensitive resin is applied as above, and thereafter, in order to dry the photosensitive resin layer 16 composed of the photosensitive resin, the layer is maintained in a heating oven heated at usually 80 to 100° C. for 1 to 2 minutes, whereby the photosensitive resin is solidified.

As shown in FIG. 1(e), on the surface of the photosensitive resin layer 16 having been thus heated and solidified in a heating oven, a photomask 18 having a desired pattern is arranged, and the photosensitive resin layer 16 is irradiated with light through the photomask 18 to expose the photosensitive resin layer to light and then developed, whereby the photosensitive resin at the portion where a wiring circuit is to be formed is removed to form a recess portion 17. At the bottom of the recess portion 17 thus formed, the sputtering copper layer 14 formed in FIG. 1(c) is exposed, as shown in FIG. 1(f). That is to say, FIG. 1(f) shows a substrate wherein a portion of the photosensitive resin layer 16 having been exposed to light is dissolved in an alkali developing solution and thereby the copper sputtering layer 14 is exposed at the bottom of the recess portion 17. In the light exposure of the photosensitive resin layer 16, the width of the wiring circuit can be controlled by changing the light exposure conditions in order to control an electric resistance value of the wiring circuit.

By subjecting the photosensitive resin layer 16 to light exposure and development as above, the copper sputtering layer 14 is exposed at the portion where the photosensitive resin has been removed. Thereafter, this substrate is transferred into a copper electroplating bath, and a plating voltage is applied between the conductive metal thin layer 12 serving as one electrode and another electrode installed in the plating bath to form a semi-additive copper layer 20 on the surface of the copper sputtering layer 14. By forming such a semi-additive layer 20, conductive resistance formed can be maintained more uniformly.

The plating solution used for forming the semi-additive copper layer 20 has a copper concentration of usually 10 to 29 g/liter, preferably 13 to 17 g/liter. In the formation of the semi-additive copper layer 20, the current density is in the range of usually 1 to 5 A/dm², preferably 1.5 to 4 A/dm², and the plating solution temperature is preset in the range of usually 18 to 25° C., preferably 20 to 25° C.

By carrying out electroplating for usually 8 to 12 minutes, preferably 9 to 11 minutes, under the above plating conditions, a semi-additive copper layer 20 having a thickness of 2 to 5 μm, preferably 2.5 to 4.5 μm, can be formed. As shown in FIG. 1(g), the semi-additive copper layer 20 thus formed does not extend in the lateral direction because both sides are regulated by the sidewalls 15 of the photosensitive resin layers 16.

Subsequently, on the surface of the semi-additive copper layer 20 formed as above, a Cu nodule layer 22 is formed, as shown in FIG. 1(h). The Cu nodules can be formed by carrying out Cu plating for several seconds at an extremely high current density using a copper plating solution obtained by adding a nodule-forming additive such as alpha-naphthoquinone to a copper sulfate plating solution that is lower than usual. The height of the individual Cu nodule thus formed is in the range of two to ten-odd μm, and a large number of nodules of such height are formed so as to overlap one another, whereby the Cu nodule layer 22 is formed. The height of the individual Cu nodule thus formed is controlled according to the pitch of the wiring circuit. For example, when the wiring circuit has a pitch of about 100 μm, the height of the individual nodule is adjusted to be 10 to 15 μm, preferably about 12 to 14 μm, and when the wiring circuit has a pitch of not more than 50 μm, the height thereof is adjusted to be not more than 6 μm, preferably 2 to 6 μm, particularly preferably about 3 to 5 μm. The Cu nodule is a Cu crystal structure formed by dendritic growth of deposited copper by changes of the electroplating conditions, and the Cu nodule layer 22 is constituted of a large number of grown Cu dendrites. In the Cu nodule layer 22, considerable voids are formed among the Cu dendrites.

The Cu nodule layer 22 is formed by allowing nodules to grow so that the upper end of the Cu nodule layer 22 and the upper end of the photosensitive resin layer 16 may become nearly equal to each other in height.

The plating solution for forming the Cu nodule layer 22 has a copper concentration of usually 6 to 10 g/liter, preferably 7 to 9 g/liter. In the formation of the Cu nodule layer 22, the current density is in the range of usually 25 to 150 A/dm², preferably 15 to 100 A/dm², and the plating solution temperature is preset in the range of usually 18 to 25° C., preferably 20 to 23° C. In order to facilitate formation of Cu nodules, an additive for forming Cu nodules, such as alpha-naphthoquinoline, is preferably added to the plating solution having the above copper concentration.

In the formation of the Cu nodule layer, electroplating is carried out for usually 1 to 15 seconds, preferably 2 to 10 seconds, whereby a Cu nodule layer 22 having a thickness of 3 to 30 μm, preferably 5 to 20 μm, can be formed.

The Cu nodules thus formed are only bonded with such a strength that they are separated when an adhesive tape having been stuck thereto is peeled. Therefore, in order to fix the Cu nodule layer 22, a cover plating layer 24 is formed, as shown in FIG. 1(i). The cover plating layer 24 can be formed by carrying out copper electroplating at a current density of usually 1 to 5 A/dm², preferably 2 to 4 A/dm², using a copper sulfate plating solution usually used. By forming the cover plating layer 24 as above, the Cu nodule layer 22 can be fixed, as shown in FIG. 1(i), and the plating layer is not separated by only peeling an adhesive film having been stuck thereto.

The plating solution for forming the cover plating layer 24 has a copper concentration of usually 10 to 20 g/liter, preferably 13 to 17 g/liter. In the formation of the cover plating 24, the current density is in the range of usually 1 to 5 A/dm², preferably 1.5 to 4 A/dm², and the plating solution temperature is preset in the range of usually 18 to 25° C., preferably 20 to 23° C.

This cover plating layer can be also formed from a metal other than copper by using, for example, a nickel plating bath containing nickel sulfamate.

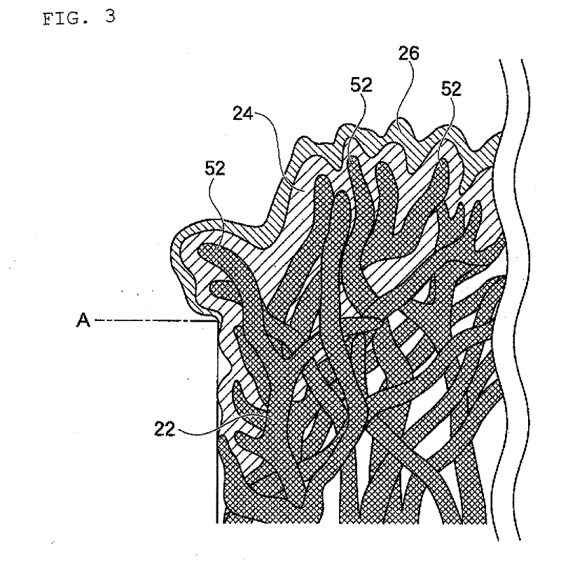

When the height of the Cu nodule layer is not less than 12 μm, the thickness of the cover plating is preferably not less than ½ of the height of the nodule, when the height of the nodule is more than 6 μm and less than 12 μm, the thickness of the cover plating is preferably ⅓ to ¼ of the height of the nodule, and when the height of the nodule is not more than 6 μm, the thickness of the cover plating is preferably not more than about ⅙ of the height of the nodule. In FIG. 1 (i), an embodiment wherein a cover plating layer 24 having a thickness of 3 to 5 μm is formed is shown. In order to show a layer structure of a printed wiring board produced by the process of the invention, the cover plating layer 24 is visualized in FIG. 1(i) as a layer having a uniform thickness by simplifying the state of the cover plating layer 24. However, the upper surface of the Cu nodule layer 22 that becomes a base for the cover plating layer 24 is not a flat surface because a large number of dendritic Cu nodules are formed, and as indicated by numeral 22 in FIG. 2 and FIG. 3, this upper surface is a surface where a large number of Cu dendrites (Cu nodules) protrude to form protrusions and depressions. If cover plating is carried out on the surface of the Cu nodule layer 22 where a large number of such Cu nodule protrusions are formed, the resulting cover plating layer 24 follows the protruded and depressed state of the surface of the Cu nodule layer 22 and reflects the protruded and depressed state of the surface of the Cu nodule layer 22. As a result, the surface of the cover plating layer 24 becomes in the same state as that of the surface of the Cu nodule layer.

For forming the cover plating layer, electroplating is carried out for usually 3 to 10 minutes, preferably 4 to 8 minutes, under the above plating conditions. Thus, an excellent cover plating layer 24 can be formed.

In the stage where the cover plating 24 has been formed as above, the side face of the wiring circuit is regulated by the sidewall 15 of the photosensitive resin layer, as shown in FIG. 1(i), and the nodules do not penetrate into the sidewall of the photosensitive resin layer. Therefore, the Cu nodules grow exclusively upward in the wiring circuit, and on the upper surface of this Cu nodule plating layer 22, the cover plating layer 24 is formed.

Although the width of the Cu nodule plating layer 22 is regulated by the sidewall 15 of the photosensitive resin layer 16 and the contact surface of such a Cu nodule plating layer 22 with the photosensitive resin layer 16 is regulated by the sidewall of the photosensitive resin layer 16, a large number of Cu nodules are formed so as to come into contact with the sidewall of the Cu nodule layer 22, and among such Cu nodules, a large number of voids are formed, as previously described. Therefore, the plating solution for forming the cover plating penetrates into the voids to form a cover plating layer 24 also on each surface of the dendritic Cu nodules that have grown in the direction of the sidewall 15 of the photosensitive resin layer 16. However, growth of the Cu nodule layer in the width direction is regulated by the sidewall 15 of the photosensitive resin layer 16, and there is no space enough to grow the cover plating layer in the width direction. Therefore, on the surface of each nodule to form the Cu nodule layer, a thin cover plating layer is merely formed. In the case where a thick gold plating layer is formed as the later-described first metal plating layer, the gold plating layer can be allowed to have a function similar to that of the cover plating layer, so that formation of the cover plating layer can be omitted.

In the present invention, after the Cu nodule layer 22 is formed as above and the cover plating layer 24 is further formed, a first metal plating layer is formed without removing the photosensitive layer 16. This first metal plating layer can be a metal plating layer, such as a gold plating layer, a tin plating layer, a nickel plating layer, a silver plating layer, a palladium plating layer, a solder plating layer or a lead-free solder plating layer, or a metal alloy plating layer containing such a metal plating layer-forming metal and another metal.

In the present invention, the first metal plating layer is particularly preferably a gold plating layer.

In the case where the first metal plating layer is a gold plating layer, the cover plating layer is formed as above and then the substrate is immersed in a gold plating bath and subjected to gold plating, whereby a gold plating layer is formed on the upper surface of the cover plating layer.

In the conventional process for producing a wiring board by etching a copper foil, etching proceeds from the upper surface of the copper foil. Therefore, the sectional width of the upper end part of the resulting wiring generally becomes smaller than the sectional width of the lower end part thereof, and a ratio of a wiring height (H) to ½ of a difference (B−A) between the sectional width (A) of the upper end part and the sectional width (B) of the lower end part of this wiring circuit, i.e., Ef={2H/(B−A)}, is given as an etching factor. As this etching factor is increased, performance of the etching solution is considered to be better. Among the etching solutions used at present, there is no excellent etching solution having an etching factor of 5 to 10, and the contact time of the upper end part of the wiring circuit with the etching solution becomes longer. Therefore, the sectional width of the upper end part becomes narrower than the sectional width of the lower end part.

In the process for producing a printed wiring board of the invention, however, the wiring circuit is not formed by etching a conductive metal foil, and therefore, such a concept of the etching factor as in the conventional printed wiring board does not exist. That is to say, in the present invention, on the whole surface of the conductive metal layer formed on the surface of the insulating base, the photosensitive resin layer 16 is formed using a photosensitive resin, then this photosensitive resin layer is exposed to light and developed to form the recess portion 17 for forming a wiring circuit, then on the recess portion 17, the semi-additive copper layer 20, the Cu nodule layer 22 and further the cover plating layer 24 are laminated, then the surface of the resulting wiring circuit is covered with the first metal plating layer (preferably gold plating layer 26), thereafter the photosensitive resin layer 16 is removed to expose the conductive metal layer at the insulating base surface, and the thus exposed conductive metal layer is removed to make the individual wiring circuits electrically independent of one another. Therefore, an etching step to selectively etching a conductive metal foil to form a wiring circuit does not exist. Moreover, the wiring circuit is formed by depositing a metal inside the recess portion 17 that is formed by exposing and developing the photosensitive resin layer 16, and the both side faces of the section of the wiring circuit are regulated by the sidewalls of the photosensitive resin layers 16 so as to be vertical to the surface of the insulating base 10. Consequently, the wiring circuit formed in the process for producing a printed wiring board of the invention has a sectional shape of a rectangle, an approximate rectangle or an inverse trapezoid.

In the present invention, the gold plating layer that is the first metal plating layer 26 can be formed by metal plating of single stage, but it is preferable that this process is divided into two stages and gold strike plating is carried out first to form a gold plating layer. By the gold strike plating, not only a material to be gold plated is activated but also a gold plating layer having high bonding property can be formed. Further, the gold plating layer formed by the gold strike plating exhibits extremely high bonding property to a plating layer formed in the subsequent step.

The plating solution for forming the gold plating layer 26 by, for example, gold strike plating as above has a gold concentration of usually 0.5 to 4 g/liter, preferably 0.8 to 3 g/liter. In the formation of the gold plating layer by gold strike plating, the current density is in the range of usually 0.1 to 7 A/dm², preferably 0.5 to 6 A/dm², and the plating solution temperature is preset in the range of usually 40 to 60° C., preferably 45 to 55° C. By carrying out electroplating for usually 3 to 30 seconds, preferably 5 to 20 seconds, under the above plating conditions, an excellent gold strike plating layer can be formed. The thickness of the gold plating layer formed by carrying out gold strike plating in the above manner is in the range of usually 0.001 to 0.2 μm, preferably 0.005 to 0.1 μm.

In the process for producing a printed wiring board of the invention, the gold plating layer is formed by carrying out gold strike plating in the above manner. However, it is also possible that after the gold strike plating is carried out as above, usual gold plating is further carried out to laminate a usual gold plating layer on the gold strike plating layer. The plating solution for the gold plating that is carried out after the gold strike plating has a gold concentration of usually 6 to 12 g/liter, preferably 7 to 10 g/liter. In the formation of the gold plating layer, the current density is in the range of usually 0.1 to 1 A/dm², preferably 0.2 to 0.6 A/dm², and the plating solution temperature is preset in the range of usually 55 to 75° C., preferably 60 to 70° C. By carrying out electroplating for usually 1 to 3 minutes, preferably 1.5 to 2.5 minutes, under the above plating conditions, a gold plating layer that is excellent as the first metal plating layer can be formed. The thickness of the first metal plating layer formed by carrying out gold plating in the above manner is in the range of usually 0.1 to 0.8 μm, preferably 0.3 to 0.6 μm, and the thickness of the gold plating layer on the upper surface of the wiring circuit, said thickness including the thickness of the gold strike plating layer formed by the aforesaid gold strike plating, is in the range of usually 0.35 to 0.55 μm, preferably 0.4 to 0.5 μm.

Although a case where the first metal plating layer 26 is a gold plating layer is described above, the first metal plating layer 26 can be formed from a metal other than gold in the present invention. That is to say, in the present invention, the first metal plating layer 26 can be a metal plating layer containing a metal other than gold, such as a tin plating layer, a nickel plating layer, a silver plating layer, a palladium plating layer, a solder plating layer or a lead-free solder plating layer, or can be a metal alloy plating layer containing such a metal and another metal.

A section of a substrate having the first metal plating layer (preferably gold plating layer) 26 formed as above is as shown in FIG. 1(j). That is to say, on the whole surface of the insulating base 10, the conductive metal thin layer 12 and the copper sputtering layer 14 are laminated in this order. On the surface of the copper sputtering layer 14, the photosensitive resin layer 16 is formed, and on the copper sputtering layer 14 on which the photosensitive resin layer 16 is not laminated, the semi-additive copper layer 20 is formed, and on the semi-additive copper layer 20, the Cu nodule layer 22 is formed. The Cu nodule layer has such a thickness that its upper surface becomes approximately flush with the upper surface of the photosensitive resin layer 16. Further, on the upper surface and the side surface of the Cu nodule layer 20, the cover plating layer 24 is formed, and moreover, the first metal plating layer (preferably gold plating layer) 26 is formed so as to cover the surface of the cover plating layer 24. The cover plating layer 24 that is formed at the position higher than that of the upper surface of the photosensitive resin layer 16 has a width equal to the width of the recess portion 17 formed by exposing and developing the photosensitive resin layer 16, or sometimes has a width a little larger than the width of the recess portion 17 because there is no regulation by the sidewall surface of the photosensitive resin layer 16. The first metal plating layer (preferably gold plating layer) 26 formed so as to cover the cover plating layer 24 has a width a litter larger than the width of the recess portion 17.

However, the width of the semi-additive copper layer 20 whose line width is regulated by the sidewall surface of the photosensitive resin layer 16 is equal to the width of the recess portion 17, and the Cu nodule layer further laminated on the semi-additive copper layer 20 has such a width that the total width of the Cu nodule layer 22 and the plating layers on the both side surfaces of the Cu nodule layer becomes equal to the width of the recess portion 17.

After the first metal plating layer (preferably gold plating layer) 26 is formed as above, the photosensitive resin layer 16 is removed. For removing the photosensitive resin layer 16, an alkali cleaning liquid, an organic solvent or the like is employable, but it is preferable to remove the photosensitive resin layer 16 using an alkali cleaning liquid. The alkali cleaning liquid does not exert evil influence on the materials constituting the printed wiring board of the invention and does not bring about environmental pollution due to evaporation of an organic solvent either.

In FIG. 1(k), a section of a substrate given after the photosensitive resin layer 16 is removed as above in the invention is shown.

When the photosensitive resin layer 16 is removed as shown in FIG. 1(k), the undercoat layer 13 consisting of the sputtering copper layer 14 and the conductive metal thin layer 12 present under the sputtering copper layer is exposed at the portion where the photosensitive resin layer 16 has been removed. The undercoat layer 13 consisting of the conductive metal thin layer 12 and the sputtering copper layer 14 has electric conduction property. Therefore, unless the undercoat layer 13 consisting of the conductive metal thin layer 12 and the sputtering copper layer 14 is removed, the resulting circuit cannot be used as an independent wiring circuit.

On the surface of the portion where the photosensitive resin layer 16 has been removed, the sputtering copper layer 14 is exposed.

It is preferable to dissolve and remove the thus exposed sputtering copper layer 14 using an etching solution capable of dissolving copper, particularly a soft etching solution exerting no evil influence on the resulting wiring circuit. The soft etching solution preferably employable for removing the sputtering copper layer 14 is, for example, a soft etching solution in which 130 to 200 g/liter of K₂S₂O₈ is dissolved. By carrying out soft etching treatment using such a soft etching solution at a temperature of 20 to 40° C., preferably a temperature in the vicinity of room temperature (usually in the vicinity of 25° C.±5° C.), for 10 seconds to 5 minutes, preferably about 30 seconds to 3 minutes, the sputtering copper layer 14 can be almost completely removed.

By dissolving and removing the sputtering copper layer 14 in the above manner, the conductive metal thin layer 12 present under the sputtering copper layer 14 is exposed.

The conductive metal thin layer 12 formed on the surface of the insulating base 10 present between wiring circuits is formed from, for example, Ni—Cr, and such a conductive metal thin layer 12 can be removed by bringing this layer into contact with an aqueous solution containing a mineral acid. In the present invention, it is particularly preferable to use a hydrochloric acid aqueous solution and a sulfuric acid/hydrochloric acid mixed aqueous solution repeatedly. As the hydrochloric acid aqueous solution, a hydrochloric acid aqueous solution having a hydrochloric acid concentration of 3 to 20% by weight, preferably 5 to 15% by weight, is employable. As the sulfuric acid/hydrochloric acid mixed aqueous solution, a mixed solution having a sulfuric acid concentration of usually 10 to 17% by weight, preferably 12 to 15% by weight, and a hydrochloric acid concentration of 10 to 17% by weight, preferably 12 to 15% by weight, is employable. In order to remove the conductive metal thin layer 12, a treatment using the above hydrochloric acid aqueous solution and a treatment using the above sulfuric acid/hydrochloric acid mixed aqueous solution are carried out in combination, and these treatments are each carried out 1 to 5 times, preferably 2 to 4 times, whereby the conductive metal thin layer 12 exposed on the surface of the insulating base 10 where the wiring circuit 1 has not been formed can be almost completely removed. The treatments with the acid aqueous solutions can be carried out by setting the time of the treatment of one time in the range of 1 to 30 seconds, preferably 5 to 30 seconds. Through the above treatments, the conductive metal thin layer 12 on the surface of the insulating base 10 where the wiring circuit 1 has not been formed can be almost completely removed, but the wiring circuit 1 is rarely influenced by the contact with the above acid aqueous solutions because the first metal plating layer (preferably gold plating layer) is formed on the wiring circuit 1.

After the treatments to remove the conductive metal thin layer 12 are carried out as above, the resulting printed wiring board is rinsed and then used as it is. However, a metal such as Ni or Cr sometimes remains on the surface of the insulating base because the conductive metal thin layer 12 was formed by sputtering as previously described, so that such a residual metal is preferably passivated. For the passivation treatment, an aqueous solution containing an oxidizing substance such as a permanganate having been adjusted to alkaline is preferably used in the invention. As the treating solution, an aqueous solution containing NaMnO₄ and/or KMnO₄, and NaOH and/or KOH is preferably used. The concentration of NaMnO₄ and/or KMnO₄ in the treating solution is in the range of usually 40 to 65 g/liter, preferably 45 to 60 g/liter, and the concentration of NaOH and/or KOH is in the range of usually 20 to 60 g/liter, preferably 30 to 50 g/liter. As the treating conditions using such an oxidizing aqueous solution, the temperature of the aqueous solution is adjusted to usually 20 to 80° C., and the treating time is in the range of 5 to 180 seconds. By carrying out such a treatment, properties of the printed wiring board are not changed by the residual metal even if a slight amount of the conductive metal remains.

After the above treatment, a reducing organic acid such as oxalic acid is introduced, whereby manganese sometimes remaining on the substrate surface can be completely removed. The oxalic acid aqueous solution preferably used herein has an oxalic acid (oxalic acid dehydrate) concentration of usually 5 to 90 g/liter, preferably 20 to 70 g/liter.

After the treatment with the oxalic acid aqueous solution is carried out as above, rinsing is carried out, whereby a printed wiring board having a wiring circuit with such a layer structure as shown in FIG. 1(m) can be obtained.

The surface layer of the wiring circuit thus formed is the first metal plating layer (preferably gold plating layer), as shown in FIG. 1(m).

In the present invention, on the surface of the wiring circuit where the first metal plating layer such as a gold plating layer has been formed, a second metal plating layer 28 can be formed from a metal other than the metal for forming the first metal plating layer 26.

That is to say, in the printed wiring board, it sometimes becomes necessary to form, as the surface layer, a tin plating layer, a solder plating layer, a lead-free solder plating layer or the like depending upon the mode of usage of the printed wiring board. For example, a printed wiring board having a wiring circuit 2 wherein on the surface of a gold plating layer 26 that is a first metal plating layer is further formed a tin plating layer 28 as a second metal plating layer is shown in FIG. 1(n).

For example, in the case where a terminal of an electronic component to be mounted on this printed wiring board is a gold bump, the surface layer of the wiring circuit is preferably a tin plating layer, and depending upon the mode of usage of the printed wiring board, on the surface of the tin plating layer can be further formed a second metal plating layer formed from a metal different from that of the first metal plating layer 26, such as a solder plating layer, a lead-free solder plating layer or a nickel plating layer. Such a second metal plating layer 28 can be formed from a metal different from the metal for forming the first metal plating layer. For example, a metal plating layer, such as a tin plating layer, a nickel plating layer, a silver plating layer, a palladium plating layer, a solder plating layer or a lead-free solder plating layer, or a metal alloy plating layer can be formed. When the first metal plating layer 26 is not a gold plating layer, the second metal plating layer can be a gold plating layer. Such a second metal plating layer 28 can be formed by a usual plating method, and for example, the above tin plating layer can be formed by electroless plating using an electroless tin plating solution.

On the surface of the printed wiring board having the wiring circuit formed as above, a solder resist layer can be formed so that the lead that becomes a connecting terminal may be exposed. In the formation of a solder resist layer, the solder resist layer can be formed after the second metal layer such as a tin plating layer is formed, or the solder resist layer is formed prior to formation of the plating layer, and then the tin plating layer can be formed at the lead portion exposed from the solder resist layer.

In the production of the printed wiring board of the invention, after the first metal plating layer is formed or after the second metal plating layer is formed, annealing can be carried out at a temperature of, for example, not lower than 100° C. By carrying out such annealing, a metal plating layer-forming metal and a metal of a layer provided with a metal plating layer sometimes diffuse mutually. Consequently, the composition of a metal plating layer to constitute a wiring circuit formed in an actually produced printed wiring board sometimes differs from the composition of metals used for forming the layer. For example, in the case where a copper layer and a tin layer are laminated, tin diffuses into the copper layer and copper diffuses into the tin layer through annealing to sometimes form a mutual diffusion layer. Occurrence of such mutual diffusion of metals is known, and in each metal layer to constitute the wiring circuit of the printed wiring board of the invention, such a mutual diffusion layer as above is sometimes formed. In the printed wiring board of the present invention, such a diffusion layer may be formed in the metal layer formed.

The printed wiring board formed as above can be used in a manner similar to that for usual printed wiring boards. However, on the surface of the wiring circuit of the printed wiring board produced by the process of the invention, protrusions and depressions attributable to formation of the Cu nodule layer are formed, as shown in FIG. 2. By utilizing these protrusions and depressions, conductive bonding to selectively establish electric conduction in the direction of pressure application can be carried out by the use of an adhesive only, without using an anisotropic conductive adhesive containing conductive particles.

FIG. 2 is a sectional view showing a state of a section of the wiring circuit when the printed wiring board produced by the process of the invention is bonded to a terminal of LCD.

As shown in FIG. 2, by forming the Cu nodule layer 22 on the sputtering copper layer 20, protrusions and depressions attributable to the nodules are formed on the surface of the Cu nodule layer 22. These protrusions and depressions of the surface of the Cu nodules layer 22 are impaired by neither the subsequent step of forming the first metal plating layer, such as cover plating or gold plating, nor the step of forming the second metal plating layer, such as electroless tin plating. The protrusions 46 thus formed are used as connecting points to a substrate of LCD.

That is to say, by interposing an adhesive 45 between the printed wiring board produced by the process of the invention and LCD and then thermally contact-bonding them under application of pressure from the upper and lower sides, the protrusions 46 of the gold metal layer 26 formed on the surface of the wiring circuit are pressure-welded to the substrate of the LCD to electrically connect the LCD and the printed wiring board to each other through the tops of the protrusions 46. On the other hand, only the adhesive 45 is present in the lateral direction to the direction of pressure application, so that insulation property in the lateral direction can be secured. As the adhesive 45, an adhesive component having been used as an anisotropic conductive adhesive in the past, such as an epoxy-based adhesive, an acrylic-based adhesive, a urethane-based adhesive or a polyamide-based adhesive, is employable. By the use of the printed wiring board produced by the process of the invention, the protrusions 46 formed on the surface of the wiring circuit are used as electrically connecting points. Therefore, there is no need to use conductive particles in the anisotropic conductive bonding, and in the adhesive, only an adhesive component is contained, so that even if the adhesive flows because of change of use environment or the like, electric conduction property in the direction of pressure application and insulation property in the lateral direction to the direction of pressure application do not vary.

On the surface of the printed wiring board produced by the process of the invention, protrusions and depressions attributable to formation of the Cu nodule layer are formed as above, and utilizing the protrusions and depressions, the printed wring board can be also connected to an electronic component or the like.

The side face 21 of the wiring circuit in the printed wiring board produced by the process of the invention is formed vertically to the insulating base 10, as shown in FIG. 2 and FIG. 3. However, each of the width of the cover plating layer 24 and the width of the first metal plating layer (preferably gold plating layer) 26 that are formed at the position higher than that of the photosensitive resin layer 16 (the position of the upper end of the photosensitive resin layer 16 is indicated by a line A-A in FIG. 2 and FIG. 3) tends to become a little larger than the width of the recess portion 17 formed by exposing and developing the photosensitive resin layer 16, but the extension is slight.

The wiring circuit formed in the printed wring board produced by the process of the invention is at about right angles to the substrate, and the upper end and the lower end of the wiring circuit are substantially equal to each other in width. In the wiring circuit 1, the first metal plating layer (preferably gold plating layer) is formed on the upper surface, and growth of Cu nodules in the lateral direction is suppressed. Therefore, anything that inhibits lateral insulation state is not present, and stable insulation between the wiring circuits is maintained for a long period of time. In the process of the invention, further, the position of the wiring circuit to be formed is determined in advance in the photosensitive resin layer by previously exposing and developing the photosensitive resin layer, and this position of the wiring circuit to be formed can be made theoretically equivalent to the wavelength of light used for the exposure. Furthermore, since there is no factor to inhibit insulation in the width direction of the wiring circuit formed, extremely fine wiring circuits can be formed at a high density.

### EXAMPLES

The present invention is further described with reference to the following examples, but it should be construed that the invention is in no way limited to those examples.

### Example 1

On a pre-treatment side surface of a polyimide film having a thickness of 35 μm, Ni—Cr (20% by weight) was sputtered in a thickness of 250 Å to form a base metal layer. On the surface of the base metal layer, copper was further sputtered in a thickness of 0.5 μm to form a copper sputtering layer. Then, a polyethylene (PET) film having a thickness of 50 μm was laminated as a reinforcing film. The thus obtained base tape was slit to a width of 35 mm to obtain a base tape for sample preparation.

The base tape was pickled in sulfuric acid, and subsequently, the surface of the copper sputtering layer of the base tape was coated with a positive typed liquid photoresist (available from Rohm & Haas Company, positive typed liquid photoresist FR200, viscosity: 18 cps) in a thickness of 9 μm by roll coating and dried in a tunnel kiln.

Then, using an exposure apparatus (manufactured by Ushio Inc.) wherein a glass photomask on which output outer lead test patterns each having 16 lines of 15 mm length and having a 50 μm pitch, a 70 μm pitch and a 100 μm pitch, respectively, had been drawn was arranged, the base tape was exposed to ultraviolet light at 360 mJ/cm².

Further, the base tape was developed with a 7% KOH solution for 80 seconds to dissolve the exposed portions, whereby photoresist patterns having the above pitches and having a thickness of 9 μm were formed.

On the base tape having the thus formed patterns of the photosensitive resin, Cu plating was carried out in a height of 2.5 μm for 3 minutes using a copper plating solution containing a copper sulfate plating additive (available from Rohm & Haas Company, Copper Gleam ST-901) under the conditions of a temperature of 25° C. and a current density of 4 A/dm² with stirring, to form a Cu semi-additive layer.

Subsequently, plating was carried out for 10 seconds under the conditions of a temperature of 25° C. and a current density of 50 A/dm² with vigorous stirring, to form a Cu nodule plating layer having a height of 7 to 9 μm. The plating solution used herein was a solution containing 32 g/liter (Cu=8 g/liter) of CuSO₄.5H₂O, 100 g/liter of H₂SO₄ and 200 ppm of alpha-naphthoquinoline (C₃H₉N).

Further, using a copper plating solution containing a copper sulfate plating additive (available from Rohm & Haas Company, Copper Gleam ST-901), cover plating was carried out for 4 minutes under the conditions of a temperature of 25° C. and a current density of 4 A/dm² with stirring, to fix the nodules.

Subsequently, using a strike gold plating solution (available form EEJA Ltd., Aurobond Tenn.), plating was carried out for 15 seconds under the conditions of 50° C. and a current density of 6 A/dm² to form a gold plating layer, and further using a gold plating solution (available form EEJA Ltd., Temperex #8400), gold plating was carried out for 2 minutes under the conditions of a temperature of 65° C. and a current density of 0.5 A/dm² to form a gold plating layer having a thickness of 0.5 μm.

After the gold plating layer was formed as above, treatment with a 10% NaOH aqueous solution was carried out at 40° C. for 30 seconds to peel the photosensitive resin layer used for forming the wiring pattern, whereby the Ni—Cr base metal layer and the Cu sputtering layer under the photosensitive resin layer were exposed.

The thus exposed Cu sputtering layer was immersed in a soft etching solution containing 150 g/liter of K₂S₂O₈ (potassium persulfate) as a main component at ordinary temperature for 1 minute to remove the Cu sputtering layer. Further, a step consisting of treating the base tape with a 9% hydrochloric acid solution at a temperature of 55° C. for 10 seconds and then treating it with a mixed solution of 13% sulfuric acid+13% hydrochloric acid at 55° C. for 10 seconds without performing rinsing was repeated three times to dissolve the Ni—Cr layer.

Subsequently, the base tape was treated with a mixed solution of 100 ml/liter of 40% NaMnO₄ and 150 ml/liter of 25% NaOH at 65° C. for 30 seconds, then rinsed and then treated with 50 g/liter of oxalic acid dihydrate at 40° C. for 30 seconds to remove manganese dioxide from the surface of the base tape, followed by rinsing.

The conductor having a line width of 60 μm was subjected to Au analysis by Scanning Auger Microscopy (SAM) before it was subjected to electroless tin plating. As a result, it was confirmed that a gold layer had been formed so as to cover the upper surface of the Cu nodule layer, and also on the upper part of the side surface, an extremely small amount of gold was detected.

On the wiring patterns formed on the base tape and provided with the gold plating layer in the above step, electroless tin plating was carried out using an electroless tin plating solution (available from Rohm & Haas Company, electroless plating solution LT-34) under the conditions of a temperature of 70° C. and a plating time of 3 minutes to form an electroless tin plating layer having a thickness of 0.5 μm.

In any of the wiring pattern having a 50 μm pitch, the wiring pattern having a 70 μm pitch and the wiring pattern having a 100 μm pitch formed as above, short-circuit did not occur. When a section of each of the resulting wiring patterns was observed, the section had a shape of a rectangle in which the width of the top of the wiring pattern was a little larger than or equal to the width of the bottom thereof.

To the 70 μm pitch pattern with nodules (line width: 40 μm, total thickness: 15 μm), an epoxy-based sheet adhesive (thickness: 25 μm) was temporarily contact-bonded under the conditions of 100° C.×3 seconds and a pressure of 2.8 kg/mm², and thereafter, a glass plate (26 mm×76 mm×0.7 mm (thickness)) with ITO having a thickness of 2500 Å was contact-bonded under the conditions of 180° C.×19.8 seconds and a pressure of 7.5 kg/mm².

The tool used herein was a tool having a width of 3 mm and a length of 110 mm made from super invar and as the thermal contact-bonding apparatus, a pulse heat bonder TC-125 manufactured by Nippon Avionics Co., Ltd. was used.

The initial connection resistance value at this time was measured, and as a result, all of 16 lines had a contact resistance value, in an area of 0.09 mm², of not more than 1Ω.

### Example 2

After a base sheet was slit to a width of 35 mm in the same manner as in Example 1, the resulting base tape was pickled in sulfuric acid. Subsequently, the Cu surface was coated with a positive typed liquid photoresist (available from Rohm & Haas Company, FR200) having been adjusted to a viscosity of 18 cps, in a thickness of 9 μm by means of a roll coater and dried in a tunnel kiln to form a photosensitive resin layer.

The photosensitive resin layer was exposed to ultraviolet light at 360 mJ/cm² by an exposure apparatus (manufactured by Ushio Inc.) using a glass photomask on which output outer lead test patterns each having 16 lines of 15 mm length and having a 50 μm pitch, a 70 μm pitch and a 100 μm pitch, respectively, had been drawn.

Further, the photosensitive resin layer was developed with a 7% KOH solution for 80 seconds to dissolve the exposed portions, whereby photoresist patterns having the above pitches and having a thickness of 9 μm were formed.

Then, using a copper plating solution containing a copper sulfate plating additive (available from Rohm & Haas Company, Copper Gleam ST-901), plating was carried out for 3 minutes under the conditions of 25° C. and 4 A/dm² with stirring to form a Cu plating circuit of 2.5 μm on the surface of the copper sputtering layer.

Subsequently, plating was carried out for 10 seconds under the conditions of a current density of 50 A/dm² to form Cu nodules having a height of 3.5 μm. The plating solution used herein was a solution containing 32 g/liter of CuSO₄.5H₂O, 100 g/liter of sulfuric acid and 200 ppm of alpha-naphthoquinoline (C₃H₉N).

After the nodules were formed as above, cover plating was carried out for 4 minutes using a copper plating solution containing a copper sulfate plating additive (available from Rohm & Haas Company, Copper Gleam ST-901) under the conditions of a temperature of 25° C. and a current density of 4 A/dm² with stirring, to fix the nodules.

Subsequently, using a strike gold plating solution (available form EEJA Ltd., Aurobond Tenn.), gold plating was carried out for 15 seconds under the conditions of a temperature of 50° C. and a current density of 6 A/dm², and further using a different gold plating solution (available form EEJA Ltd., Temperex #8400), plating was carried out for 2 minutes under the conditions of a temperature of 65° C. and a current density of 0.5 A/dm² to form a gold plating layer having a thickness of 0.5 μm.

Thereafter, treatment with a 10% NaOH aqueous solution was carried out at 40° C. for 30 seconds to peel the photosensitive resin layer, and then, using a soft etching solution containing 150 g/liter of K₂S₂O₈ (potassium persulfate) as a main component, etching was carried out at ordinary temperature for 1 minute to remove the Cu sputtering layer, whereby the Ni—Cr layer was exposed.

Then, a step consisting of treating the base tape with a 9% hydrochloric acid solution at 55° C. for 10 seconds and then treating it with a mixed solution of 13% sulfuric acid+13% hydrochloric acid at 55° C. for 10 seconds without performing rinsing was repeated three times to remove the Ni—Cr layer by dissolution.

Further, the base tape was treated with a mixed solution of 100 ml/liter of 40% NaMnO₄ and 150 ml/liter of 25% NaOH at 65° C. for 35 seconds, then rinsed and then treated with 50 g/liter of oxalic acid dihydrate at 40° C. for 30 seconds to remove manganese dioxide, followed by rinsing.

The gold plating layer was formed as above, and before tin plating was carried out, the 50 μm pitch portion (nodule height: 9 μm, total thickness 16 μm, line width: 30 μm) was thermally contact-bonded in the same manner as in Example 1, and electric resistance in a connection area of 0.12 mm² was measured. As a result, the electric resistance was not more than 1Ω.

### Example 3

After a base sheet was slit to a width of 35 mm in the same manner as in Example 1, the resulting base tape was pickled in sulfuric acid. Subsequently, the surface of the Cu sputtering layer of the base tape was coated with a positive typed liquid photoresist (available from Rohm & Haas Company, positive typed liquid photoresist FR200, viscosity: 18 cps) in a thickness of 8 μm by roll coating and dried in a tunnel kiln.

Then, using an exposure apparatus (manufactured by Ushio Inc.) wherein a glass photomask on which output outer lead test patterns each having 16 lines of 15 mm length and having a 20 μm pitch, a 50 μm pitch and a 70 μm pitch, respectively, had been drawn was arranged, the base tape was exposed to ultraviolet light at 360 mJ/cm².

Further, the base tape was developed with a 7% KOH solution for 80 seconds to dissolve the exposed portions, whereby photoresist patterns having the above pitches and having a thickness of 8 μm were formed.

On the base sheet having the thus formed patterns of the photosensitive resin, Cu plating was carried out in a height of 3.5 μm for 5 minutes using a copper plating solution containing a copper sulfate plating additive (available from Rohm & Haas Company, Copper Gleam ST-901) under the conditions of a temperature of 25° C. and a current density of 3 A/dm² with stirring, to form a Cu semi-additive layer.

Subsequently, plating was carried out for 3 seconds under the conditions of a temperature of 25° C. and a current density of 50 A/dm² with vigorous stirring, to form a Cu nodule plating layer having a height of 7 μm. The plating solution used herein was a solution containing 32 g/liter (Curs g/liter) of CuSO₄.5H₂O, 100 g/liter of H₂SO₄ and 200 ppm of alpha-naphthoquinoline (C₃H₉N).

Further, using a copper plating solution containing a copper sulfate plating additive (available from Rohm & Haas Company, Copper Gleam ST-901), cover plating was carried out for 2 minutes under the conditions of a temperature of 25° C. and a current density of 3 A/dm² with stirring, to fix the nodules.

Thereafter, treatment with a 10% NaOH aqueous solution was carried out at ordinary temperature for 15 seconds to peel the photosensitive resin layer used for forming the wiring pattern, whereby the Cu sputtering layer under the photosensitive resin layer and the Ni—Cr base metal layer under the Cu sputtering layer were exposed.

The thus exposed Cu sputtering layer was immersed in a soft etching solution containing 150 g/liter of K₂S₂O₈ (potassium persulfate) as a main component at 30° C. for 30 seconds to remove the Cu sputtering layer. Then, a step consisting of treating the base tape with a 9% hydrochloric acid solution at a temperature of 55° C. for 10 seconds and then treating it with a mixed solution of 13% sulfuric acid+13% hydrochloric acid at 55° C. for 10 seconds without performing rinsing was repeated twice to dissolve the Ni—Cr layer. In this step, Cu was also etched a little to decrease the nodule height and the conductor width by several μm.

Subsequently, the base tape was treated with a mixed solution of 100 ml/liter of 40% NaMnO₄ and 150 ml/liter of 25% NaOH at 65° C. for 30 seconds, then rinsed and then treated with 50 g/liter of an aqueous solution of oxalic acid dihydrate at 40° C. for 30 seconds to remove manganese dioxide from the surface of the base tape, followed by rinsing.

Finally, the base tape was pickled in a 10% sulfuric acid aqueous solution at 30° C. for 10 seconds, then rinsed and then subjected to electroless tin plating at 70° C. for 2.5 minutes using an electroless tin plating solution (LT-34, available from Rohm & Haas Company) to form an electroless tin plating layer having a thickness of 0.5 μm on the whole of the conductor.

While the electroless tin plating layer was annealed at 125° C. for 1 hour, an epoxy-based adhesive (thickness: 25 μm) was placed on the 20 μm pitch pattern (nodule height: 3 μm, total thickness: 6.5 μm, top line width: 7 μm), and the epoxy-based adhesive was temporarily contact-bonded to the pattern at 100° C. for 3 seconds under a pressure of 1.5 kg/mm². Thereafter, a glass plate (26 mm×76 mm×0.7 mm (thickness)) with ITO having a thickness of 2500 A was contact-bonded at 180° C. for 19.8 seconds under a pressure of 2.5 kg/mm².

The tool used herein was a tool having a width of 3 mm and a length of 110 mm made from super invar and as the thermal contact-bonding apparatus, a pulse heat bonder TC-125 manufactured by Nippon Avionics Co., Ltd. was used.

The initial connection resistance value at this time was measured, and as a result, all of 16 lines had a contact resistance value, in a connection area of 0.04 mm², of not more than 1Ω.

### Comparative Example 1

After a base tape having a width of 35 mm formed in the same manner as in Example 1 was pickled in a sulfuric acid aqueous solution, the Cu surface was coated with a positive typed liquid photoresist (available from Rohm & Haas Company, FR200, viscosity: 18 cps) in a thickness of 9 μm by roll coating and dried in a tunnel kiln. Thereafter, using a glass photomask on which output outer lead test patterns each having 16 lines of 15 mm length and having a 50 μm pitch, a 70 μm pitch and a 100 μm pitch, respectively, had been drawn, the base tape was exposed to ultraviolet light at 360 mJ/cm² by an exposure apparatus (manufactured by Ushio Inc.)

Further, the base tape was developed with a 7% KOH solution for 80 seconds to dissolve the exposed portions, whereby photoresist patterns having the above pitches and having a thickness of 9 μm were formed.

Then, using a copper sulfate plating solution (available from Rohm & Haas Company, Copper Gleam ST-901 was added), plating was carried out for 10 minutes under the conditions of a temperature of 25° C. and a current density of 4 A/dm² to form a Cu plating circuit having a height of 9 μm. Under these plating conditions, any nodule was not formed. Subsequently, gold plating was carried out on the Cu plating circuit in the same manner as in Example 1.

The 70 μm pitch pattern with no nodule that had not been subjected to tin plating was thermally contact-bonded in the same manner as in Example 1. The initial connection resistance value in a connection area of 0.12 mm² at this time was measured. As a result, all of 16 lines had a connection resistance value of not less than 10Ω, and some connection parts had a connection resistance value of several mega Ω level.

That is to say, it has been found that when any nodule is not formed on the pattern, electrical connection is impossible. The results are set forth in Table 1.

Table 1

TABLE 1
Results of thermal contact-bonding test of nodule (initial resistance value)

| Pitch | 50 μm | 70 μm | 20 μm | 70 μm |
|---|---|---|---|---|
| Surface layer | gold plating layer | gold plating layer + | tin plating layer | gold plating layer |
| | | tin plating layer | | (no tin plating |
| | | | | layer) |
| Height of nodule | 9 μm | 7 μm | 3 μm | no nodule |
| Terminal number | 0.09 mm² | 0.12 mm² | 0.04 mm² | 0.12 mm² |
| (connection | | | | |
| resistance) | | | | |
| 1 | 1 Ω or less | 1 Ω or less | 1 Ω or less | connection |
| | | | | failure |
| 2 | 1 Ω or less | 1 Ω or less | 1 Ω or less | 60 KΩ |
| 3 | 1 Ω or less | 1 Ω or less | 1 Ω or less | 35 KΩ |
| 4 | 1 Ω or less | 1 Ω or less | 1 Ω or less | connection |
| | | | | failure |
| 5 | 1 Ω or less | 1 Ω or less | 1 Ω or less | 73 KΩ |
| 6 | 1 Ω or less | 1 Ω or less | 1 Ω or less | connection |
| | | | | failure |
| 7 | 1 Ω or less | 1 Ω or less | 1 Ω or less | connection |
| | | | | failure |
| 8 | 1 Ω or less | 1 Ω or less | 1 Ω or less | connection |
| | | | | failure |
| 9 | 1 Ω or less | 1 Ω or less | 1 Ω or less | 462 Ω |
| 10 | 1 Ω or less | 1 Ω or less | 1 Ω or less | 29 Ω |
| 11 | 1 Ω or less | 1 Ω or less | 1 Ω or less | 5400 Ω |
| 12 | 1 Ω or less | 1 Ω or less | 1 Ω or less | 5700 Ω |
| 13 | 1 Ω or less | 1 Ω or less | 1 Ω or less | 13 MΩ |
| 14 | 1 Ω or less | 1 Ω or less | 1 Ω or less | 36 MΩ |
| 15 | 1 Ω or less | 1 Ω or less | 1 Ω or less | connection |
| | | | | failure |
| 16 | 1 Ω or less | 1 Ω or less | 1 Ω or less | 2 MΩ |
| Results | good | good | good | bad |

Notes:

For bonding, an epoxy-based adhesive sheet of 25 μm thickness was used.

Bonding conditions: thermal contact-bonding under the conditions of 180° C.×19.8 seconds×2 kg/cm² (A tool of 3 mm width was used.)

A glass plate (26 mm×76 mm×0.7 mm^{t}) with ITO was bonded to each of the samples produced in the examples and the comparative examples.

### INDUSTRIAL APPLICABILITY

The printed wiring board of the invention is produced by exposing and developing a photosensitive resin layer formed on a surface of an undercoat layer of an insulating base to previously form a recess portion where a wiring circuit is to be formed and then laminating a plating layer on the recess portion to form a wiring circuit, and the thus formed wiring circuit has a sectional shape of a rectangle that is vertical to the insulating base. Further, in the wiring circuit having a sectional shape of a rectangle formed in the printed wiring board, the width of the upper end and the width of the lower end are approximately equal to each other, or the width of the upper end is slightly larger than the width of the lower end, and the sectional shape rises up very sharply from the insulating base. Furthermore, the growing direction of nodules in a Cu nodule layer to constitute the wiring circuit is the thickness direction of the wiring circuit, and in the formation of the Cu nodule layer, the lateral direction is blocked by the sidewall of the pattern made of the photosensitive resin, so that nodules do not grow in the lateral direction of the wiring circuit. On this account, extremely fine wiring circuits can be formed at a high density, and even if wiring circuits are formed at a high density, short-circuit does not occur between the adjacent wiring circuits.

In the wiring circuit of the printed wiring board of the invention, a Cu nodule layer is formed on a sputtering copper layer in the recess portion obtained by exposing and developing a photosensitive resin layer, and thereon, a cover plating layer and a first metal plating layer (preferably gold plating layer) are further laminated. On the surface of the thus formed conductor, a large number of protrusions and depressions attributable to the formation of the Cu nodule layer are formed. Utilizing the protrusions and depressions, conductive bonding can be carried out by the use of an adhesive only without using conductive particles.

In the case where the first metal plating layer is Au plating, Kirkendall voids due to mutual diffusion are not formed at the interface between Cu that is a conductor of the wiring circuit and the Au plating even after high-temperature heating is performed for a long period of time, and therefore, contact resistance of the connection part is not increased. In the case where the first metal plating layer is an Sn plating layer, Kirkendall voids are sometimes formed, so that as the first metal plating layer, the gold plating layer is more advantageous than the tin plating layer, from the viewpoint of occurrence of viods. By forming the gold plating layer as the first metal plating layer, further, storage stability is also enhanced.

On the other hand, in the case where a bump electrode formed on an electronic component to be mounted is a gold bump, it is preferable that tin is fed from a terminal on the printed wiring board side to form a gold-tin eutectic together with gold of the gold bump in order to electrically connect the gold bump of the electronic component to the printed wiring board. In this case, by forming an electroless tin plating layer as the second metal plating layer, mounting of the electronic component can be surely carried out.

This second metal plating layer is formed so as to cover the whole of the wiring circuit including the side face of the Cu nodule layer present on the side face of the wiring circuit, and therefore, anti-corrosion property formed tends to be enhanced.

In the printed wiring board of the invention, electric resistance values of wirings formed in the same printed wiring board are preferably within the range of a central value ±10 irrespective of the length of the wiring that is led about. By the use of such a printed wiring board having high uniformity, dispersion of an output signal of the electric signals led out from the output side outer lead, said dispersion being attributed to variability of electric insulation property of the wiring circuit, is decreased, and more precise wiring circuits can be formed.

In the case where plural printed wiring boards in each of which such circuits as above are formed are arranged in parallel, it is of course desirable to produce the printed wiring boards so that the mean values of their electric resistance values may become more uniform, and it is also desirable not only to approximate mean values of wiring circuits of a large number of wirings between the output side inner lead and the output side outer lead to one another but also to minimize a difference in electric resistance between the adjacent wiring circuits that are formed on the outermost side of the plural printed wiring boards arranged in parallel.

1. A printed wiring board having an insulating base and a plurality of wiring circuits formed on a surface of the insulating base, wherein the wiring circuit has a conductive undercoat layer formed on the surface of the insulating base, a Cu nodule layer formed on an upper surface of the undercoat layer, a cover plating layer formed on an upper surface of the Cu nodule layer and a first metal plating layer formed on an upper surface of the cover plating layer, and on an upper surface of the wiring circuit, a protruded and depressed surface attributable to protrusions and depressions of the upper surface of the Cu nodule layer is formed.

2. The printed wiring board as claimed in claim 1, wherein the undercoat layer comprises a conductive metal thin layer composed of a Ni—Cr alloy and a sputtering copper layer.

3. The printed wiring board as claimed in claim 1, which has a semi-additive copper layer on the upper surface of the conductive undercoat layer.

4. The printed wiring board as claimed in claim 1, wherein the first metal plating layer is at least one metal plating layer selected from the group consisting of a gold plating layer, a tin plating layer, a nickel plating layer, a silver plating layer, a palladium plating layer, a solder plating layer and a lead-free solder plating layer, or a metal alloy plating layer containing the plating layer-forming metal and another metal.

5. The printed wiring board as claimed in claim 1, wherein a second metal plating layer composed of a metal different from that of the first metal plating layer is formed on the upper surface and the side surface of the wiring circuit.

6. The printed wiring board as claimed in claim 1, wherein the section of the wiring circuit has a shape of a rectangle or an approximate rectangle.

7. The printed wiring board as claimed in claim 1, wherein the Cu nodules to constitute the Cu nodule layer selectively grow in the thickness direction of the wiring circuit.

8. A process for producing a printed wiring board, comprising forming a conductive undercoat layer for supplying plating power on a surface of an insulating base, forming a photosensitive resin layer on a surface of the undercoat layer, exposing and developing a pattern for forming a wiring circuit in the photosensitive resin layer to form a recess portion on the photosensitive resin layer, forming a Cu nodule layer inside the recess portion, forming a cover plating layer on tea surface of the Cu nodule layer, further forming a first metal plating layer on at least an upper surface of the cover plating layer on the thus formed Cu nodule layer to cover an upper surface of the Cu nodule layer, thereafter peeling the photosensitive resin layer and then removing the undercoat layer having been exposed by peeling the photosensitive resin layer.

9. A process for producing a printed wiring board, comprising forming a conductive undercoat layer for supplying plating power on a surface of an insulating base, forming a photosensitive resin layer on a surface of the undercoat layer, exposing and developing a pattern for forming a wiring circuit in the photosensitive resin layer to form a recess portion on the photosensitive resin layer, forming a Cu nodule layer inside the recess portion, forming a cover plating layer on a surface of the Cu nodule layer, further forming a gold plating layer on at least the an upper surface of the cover plating layer formed on the Cu nodule layer to cover an upper surface of the Cu nodule layer, thereafter peeling the photosensitive resin layer and then removing the undercoat layer having been exposed by peeling the photosensitive resin layer.

10. The process for producing a printed wiring board as claimed in claim 8, wherein the undercoat layer comprises a conductive metal thin layer composed of a Ni—Cr alloy and a sputtering copper layer.

11. The process for producing a printed wiring board as claimed in claim 8, wherein the photosensitive resin layer is formed on the surface of the undercoat layer, the photosensitive resin layer is exposed and developed to form the recess portion for forming a wiring circuit, then a semi-additive copper layer is formed on the undercoat layer surface exposed at the recess portion, and the Cu nodule layer is formed on the surface of the semi-additive copper layer.

12. The process for producing a printed wiring board as claimed in claim 8, wherein the cover plating layer and the first metal plating layer or the gold plating layer are formed on the surface of the Cu nodule layer so as to reflect the protruded and depressed surface that is formed on the upper surface of the Cu nodule layer.

13. The process for producing a printed wiring board as claimed in claim 9, wherein the gold plating treatment is carried out in two stages, and gold strike plating is carried out first.

14. The process for producing a printed wiring board as claimed in claim 8, wherein after the wiring circuit is formed, the photosensitive resin layer is peeled, and the undercoat layer having been exposed by peeling the photosensitive resin layer is brought into contact with a strongly acidic aqueous solution to remove the undercoat layer.

15. The process for producing a printed wiring board as claimed in claim 8, wherein a part of the undercoat layer is brought into contact with a hydrochloric acid to remove the part of the undercoat layer, and the residual part of the undercoat layer is removed by a sulfuric acid/hydrochloric acid mixed aqueous solution.

16. The process for producing a printed wiring board as claimed in claim 14, wherein after the undercoat layer is removed by dissolution, a treatment with an alkali aqueous solution containing a permanganate is carried out.

17. The process for producing a printed wiring board as claimed in claim 16, wherein the printed wiring board having been treated with the alkali aqueous solution containing a permanganate is treated with an aqueous solution containing oxalic acid.

18. The process for producing a printed wiring board as claimed in claim 8, wherein after the undercoat layer is removed, an electroless tin plating layer is formed as a second metal plating layer on the surface of the wiring circuit where the gold plating layer or the first metal plating layer has been formed.

19. An anisotropic conductive bonding method for a printed wiring board, comprising using the printed wiring board of claim 1 and bonding the printed wiring board having the wiring circuit that has, on its surface, protrusions attributable to the Cu nodule layer to a substrate provided with a connecting terminal under pressure using an adhesive containing no conductive particle to selectively make electrical connection in the direction of pressure application.

20. The process for producing a printed wiring board as claimed in claim 9, wherein the undercoat layer comprises a conductive metal thin layer composed of a Ni—Cr alloy and a sputtering copper layer.
